(19) United States
(12) Patent Application Publication
(10) Pub. No.: US 2017/0032987 A1
(43) Pub. Date: Feb. 2, 2017

(54) DRY ETCHING APPARATUS

(71) Applicant: Samsung Electronics Co., Ltd., Suwon-si (KR)

(72) Inventors: Hyung-Joo LEE, Hwaseong-si (KR); Kwang-Nam KIM, Suwon-si (KR); Jong-Seo HONG, Yongin-si (KR); Kye-Hyun BAEK, Suwon-si (KR); Masayuki TOMOYASU, Seongnam-si (KR)

(21) Appl. No.: 15/096,555

(22) Filed: Apr. 12, 2016

(30) Foreign Application Priority Data
Jul. 30, 2015 (KR) 10-2015-0107688

(51) Int. Cl. H01L 21/67; H01J 37/32; H01L 21/683

(52) U.S. Cl. CPC H01L 21/67069; H01L 21/6831; H01J 37/32009; H01J 37/32642; H01J 2237/334

(57) ABSTRACT

Disclosed are a dry etching apparatus and a method of etching a substrate using the same. The apparatus includes a base at a lower portion of process chamber in which a dry etching process is performed, a substrate holder arranged on the base and holding a substrate on which a plurality of pattern structures is formed by the etching process, a focus ring enclosing the substrate holder and uniformly focusing an etching plasma to a sheath area over the substrate, a driver driving the focus ring in a vertical direction perpendicular to the base and a position controller controlling a vertical position of the focus ring by selectively driving the driver in accordance with inspection results of the pattern structures. Accordingly, the gap distance between the substrate and the focus ring is automatically controlled to thereby increase the uniformity of the etching plasma over the substrate.

### CROSS-REFERENCE TO RELATED APPLICATIONS

This application claims the benefit of priority under 35 U.S.C §119 to Korean Patent Application No. 10-2015-0107688, filed on Jul. 30, 2015, in the Korean Intellectual Property Office, the disclosure of which is incorporated by reference herein in its entirety.

### BACKGROUND

1. Field

Example embodiments relate to a dry etching apparatus, and more particularly, to a plasma etching apparatus in which the substrate may be etched by using plasma.

2. Description of the Related Art

Plasma etching processes are widely used for forming fine patterns for semiconductor devices. In plasma etching processes, source gases are transformed into source plasma in the process chamber, and the active ions or radicals in the source plasma are guided onto the substrate on an electrostatic chuck (ESC). Then, the thin layers on the substrate are etched off by the active ions or radicals in the source plasma.

The uniform etching against the thin layer along the substrate generally requires a uniform distribution of the source plasmas along a whole surface of the substrate. Usually, a focus ring is installed along the ESC in the etching apparatus so as to increase the uniformity of the source plasma along the whole surface of the substrate.

Typically, the substrate is arranged on the ESC, and the focus ring is arranged around the ESC in such a way that the ESC is enclosed by the focus ring. Thus, the source plasma is focused to an area over the substrate that may be enclosed by the focus ring, to thereby form a uniform plasma sheath over the substrate.

However, the focus ring itself is etched off by the source plasma and thus the height of the focus ring gradually decreases as the plasma etching process progresses. Thus, the surface profile of the ESC and the focus ring is gradually changed in the course of the plasma etching process. The change of the surface profile of the ESC and the focus ring usually causes a change in the distribution of the source plasma over the substrate, and as a result, the density of the active ions or radicals may vary along the surface of the substrate. As a result of the change of the surface profile of the ESC and the focus ring, there is often a deterioration of uniform etching against the thin layers on the substrate.

Recent semiconductor technology trends, including large wafers and reduced chip sizes, may cause a significant yield drop at an edge portion of the substrate.

Since the edge portion of the substrate moves farther away from the ESC as the substrate is enlarged, the uniformity deterioration of the source plasma caused by the change of the surface profile of the ESC and the focus ring may occur more frequently at the edge portion of the substrate, so that the etching failures occur more frequently at the edge portion of the substrate. Therefore, because of the recent semiconductor technology trends, the yield of semiconductor devices tends to be reduced at the edge portion of the substrate.

In particular, since the reduction of the chip size typically requires fine and high aspect ratio patterns, a small change of the source plasma uniformity may cause etching failures at the edge portion of the substrate, which may more seriously deteriorate the yield of the semiconductor devices at the edge portion of the substrate.

Accordingly, there has been a need for an improved plasma etching apparatus in which the height of the focus ring is automatically controlled as the plasma etching process makes progress so as to prevent the uniformity deterioration of the source plasma over the substrate.

### SUMMARY

Example embodiments provide a dry etching apparatus in which the height of the focus ring may be automatically controlled to thereby prevent the deterioration of the uniformity of the source plasma.

According to certain example embodiments, the disclosure is directed to a dry etching apparatus, comprising: a base at a lower portion of a dry etching process chamber; a substrate holder arranged on the base and configured to hold a substrate; a focus ring enclosing the substrate holder and configured to uniformly focus an etching plasma to a sheath area over the substrate while a plurality of pattern structures are formed on the substrate; a driver for driving the focus ring in a vertical direction perpendicular to the base; and a position controller configured to control a vertical position of the focus ring by selectively driving the driver based on inspection results of the pattern structures.

In some aspects, the disclosure further includes wherein the driver includes: a support plate for supporting the focus ring; a connecting rod connected to the support plate and configured to move the support plate upwards and downwards in the vertical direction; a driving shaft for driving the connecting rod; and a power source for generating a driving power for driving the connecting rod.

In some aspects, the disclosure further includes wherein the substrate holder includes: a chuck body arranged on the base and having a lower electrode to which a high frequency electrical power is applied; an insulating ring for enclosing the chuck body on the base; and a securing chuck arranged on the chuck body and configured to secure the substrate, wherein the connecting rod extends into the base through the insulating ring, and wherein the driving shaft is connected to the power source and the connecting rod in the base.

In some aspects, the disclosure further includes wherein the support plate is ring-shaped and interposed between a bottom surface of the focus ring and upper surfaces of the chuck body and the insulating ring.

In some aspects, the disclosure further includes wherein the connecting rod includes three slender members that are arranged in the vertical direction symmetrically with one another and at an angle of 120° with respect to a central axis of the substrate holder.

In some aspects, the disclosure further includes wherein the driver includes: a sealing member interposed between the insulating ring and the base; and a leveler for controlling a level degree of the connecting rod.

In some aspects, the disclosure further includes wherein the position controller includes: a data port configured to receive inspection data from the inspection results of the pattern structures; a position signal generator configured to generate a position signal including a correct position of the focus ring when the inspection data is deviated from reference data; and a driving signal generator for generating a driving signal that drives the focus ring to move to the correct position.

In some aspects, the disclosure further includes wherein the driving signal generator includes: an encoder configured to detect a current position of the focus ring; a distance calculator configured to generate a correct distance corresponding to a position difference between the current position and the correct position; and a signal generator configured to generate a power signal that is applied to the power source and drives the connecting rod to move in the vertical direction by the correct distance.

In some aspects, the disclosure further includes wherein the power source includes a servo motor that is arranged in the base.

In some aspects, the disclosure further includes wherein the substrate holder is smaller than the substrate such that the substrate holder is covered with the substrate and an edge portion of the substrate is spaced apart from the substrate holder, wherein the focus ring includes a lower top surface that is below a bottom surface of the edge portion of the substrate, an upper top surface that is above a top surface of the substrate, and a slant surface connected to the lower top surface and the upper top surface, and wherein the position controller includes a stopper for stopping the focus ring from moving upwards and thereby prevent the contact of the lower top surface of the focus ring and the bottom surface of the substrate.

In some aspects, the disclosure further includes wherein the stopper includes: a gap detector configured to detect a gap distance in the vertical direction between the lower top surface of the focus ring and the bottom surface of the substrate; a stopping signal generator configured to generate a stopping signal for stopping the focus ring from moving upwards when the gap distance is smaller than a minimal gap distance; and a destructive signal generator configured to generate a destructive signal for cancelling the driving signal by a destructive interference in response to the stopping signal.

In some aspects, the disclosure further includes wherein the stopper includes: a gap calculator configured to calculate a gap distance in the vertical direction by subtracting a moving distance of the focus ring to the correct position from an initial gap distance between the lower top surface of the focus ring and the bottom surface of the substrate at an initial time of the etching process; a stopping signal generator configured to generate a stopping signal for stopping the focus ring from moving upwards when the calculated gap distance is smaller than a reference distance; and a destructive signal generator configured to generate a destructive signal for cancelling the driving signal by a destructive interference in response to the stopping signal.

In some aspects, the disclosure further includes an automatic process controller configured to control the dry etching apparatus according to a process algorithm and generate an inspection database from the inspection data that is periodically obtained from the inspection results of the pattern structures and is sorted by inspection items.

In some aspects, the disclosure further includes wherein the data port is communicatively coupled with the inspection database.

In some aspects, the disclosure further includes wherein the inspection items include at least one of a composition of the pattern structure, a line width of the pattern structure, and an etching depth of the dry etching process.

According to certain example embodiments, the disclosure is directed to a dry etching apparatus comprising: a dry etching process chamber; a base arranged at a lower portion of the process chamber; a substrate holder arranged on the base and configured to hold a substrate; a focus ring enclosing the substrate holder and configured to form a sheath area over the substrate; a support plate interposed between a bottom surface of the focus ring and the substrate holder; a connecting rod connected to the support plate and configured to move the support plate in a direction toward and away from the base; and a position controller configured to control a vertical position of the focus ring by selectively driving the connecting rod based on inspection results of pattern structures formed on the substrate.

In some aspects, the disclosure further includes a driving shaft configured to drive the connecting rod; and a power source configured to generate a driving power to drive the connecting rod.

In some aspects, the disclosure further includes wherein the substrate holder includes: a chuck body arranged on the base and having a lower electrode to which a high frequency electrical power is applied; an insulating ring enclosing the chuck body on the base; and a securing chuck arranged on the chuck body and configured to secure the substrate, wherein the connecting rod extends into the base through the insulating ring, and wherein the driving shaft is connected to the power source and the connecting rod in the base.

According to certain example embodiments, the disclosure is directed to a dry etching apparatus comprising: a base arranged at a lower portion of a dry etching process chamber; a substrate holder arranged on the base and configured to hold a substrate; a focus ring encircling the substrate holder to form a sheath area over the substrate; a support plate interposed between a bottom surface of the focus ring and the substrate holder; a connecting rod connected to the support plate for moving the support plate in a vertical direction perpendicular to the base; and a position controller configured to drive the connecting rod and control a vertical position of the focus ring, the position controller including: a data port configured to receive inspection data from inspection results of the pattern structures for inspection items, wherein the inspection items include at least one of a composition of the pattern structure, a line width of the pattern structure, and an etching depth, a position signal generator configured to generate a position signal including a correct position of the focus ring, and a driving signal generator configured to generate a driving signal to move the focus ring to the correct position.

In some aspects, the disclosure further includes wherein the driving signal generator includes: an encoder configured to detect a current position of the focus ring; a distance calculator configured to generate a correct distance corresponding to a difference between the current position and the correct position; and a signal generator configured to generate a power signal that is applied to a power source and drive the connecting rod to move in the vertical direction by the correct distance.

### BRIEF DESCRIPTION OF THE DRAWINGS

These and other features will become more apparent by describing in detail exemplary embodiments thereof with reference to the accompanying drawings of which:

FIG. 1 is a structural view illustrating a dry etching apparatus in accordance with an example embodiment;

FIG. 2 is a cross-sectional view illustrating the substrate holder and the focus ring of the exemplary dry etching apparatus shown in FIG. 1;

FIG. 3 is a perspective view illustrating the exemplary focus ring shown in FIG. 2;

FIG. 4A is a block diagram showing the position controller of the exemplary dry etching apparatus shown in FIG. 1;

FIG. 4B is a block diagram showing a modification of the exemplary position controller shown in FIG. 4A;

FIG. 5 is a flow chart showing processing steps for an exemplary method of etching a substrate using the dry etching apparatus shown in FIG. 1; and

FIG. 6 is a flow chart showing the process steps for an exemplary method of automatically moving the focus ring upwards shown in FIG. 5.

### DETAILED DESCRIPTION OF THE EMBODIMENTS

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, the size and relative sizes of layers and regions may be exaggerated for clarity. Like numbers refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, or as “contacting” or “in contact with” another element, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. Unless the context indicates otherwise, these terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will typically have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature, their shapes are not intended to limit the scope of the example embodiments.

Although the figures described herein may be referred to using language such as “one embodiment,” or “certain embodiments,” these figures, and their corresponding descriptions are not intended to be mutually exclusive from other figures or descriptions, unless the context so indicates. Therefore, certain aspects from certain figures may be the same as certain features in other figures, and/or certain figures may be different representations or different portions of a particular exemplary embodiment.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein. As used herein, items described as being “fluidly connected” are configured such that a liquid or gas can flow, or be passed, from one item to the other.

The semiconductor devices described herein may be part of an electronic device, such as a semiconductor memory chip or semiconductor logic chip, a stack of such chips, a semiconductor package including a package substrate and one or more semiconductor chips, a package-on-package device, or a semiconductor memory module, for example. In the case of memory, the semiconductor device may be part of a volatile or non-volatile memory.

Reference will now be made to example embodiments, which are illustrated in the accompanying drawings, wherein like reference numerals may refer to like components throughout.

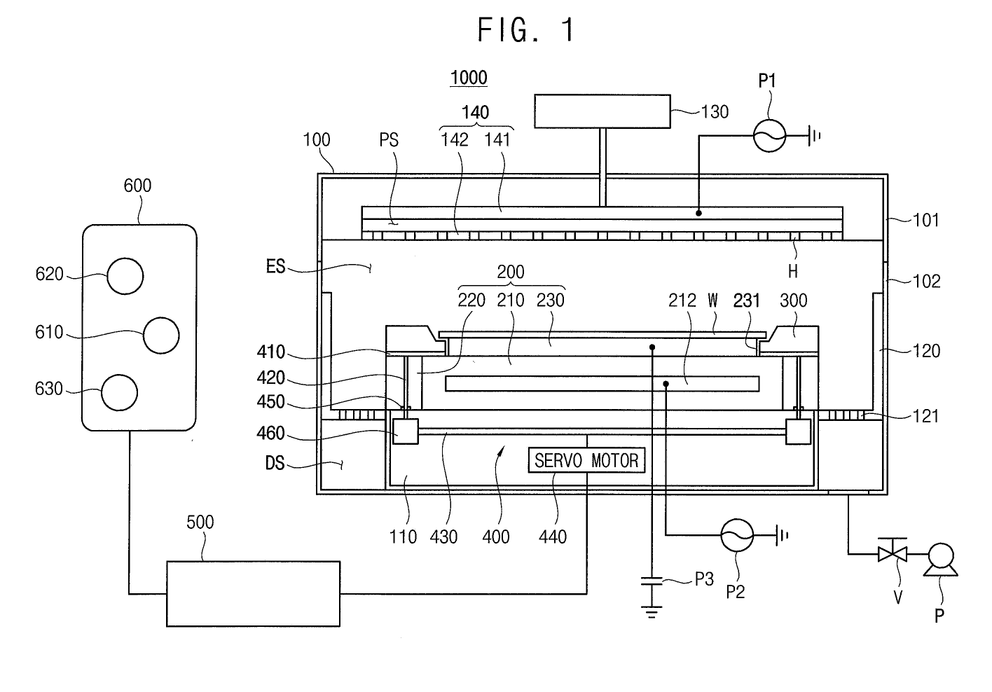

FIG. 1 is a structural view illustrating a dry etching apparatus, according to certain example embodiments. Hereinafter, a plasma etching process will be exemplarily described as a dry etching process. However, any other dry etching process can also be performed in the present dry etching apparatus 1000.

Referring to FIG. 1, the dry etching apparatus 1000 in accordance with example embodiments may include a process chamber 100 having a base 110 and a plasma generator 140 and performing a dry etching process, a substrate holder 200 arranged on the base 110 at a lower portion of the process chamber 100 and holding a substrate W on which a plurality of pattern structures are formed by the dry etching process, a focus ring 300 enclosing the substrate holder 200 and uniformly focusing an etching plasma to a sheath area over the substrate W, a driver 400 driving the focus ring 300 in a vertical direction perpendicular to the base 110, and a position controller 500 controlling a vertical position of the focus ring 300 by selectively driving the driver 400 in accordance with inspection results of the pattern structures. An automatic process controller 600 may be further provided with the dry etching apparatus 1000 at a location outside of the process chamber 100, to thereby control the dry etching process according to a process algorithm and generate an inspection database from the inspection data. The inspection on the pattern structures may be repeatedly and periodically conducted after the dry etching process, and the inspection data may be periodically obtained from the inspection results based on the items inspected.

For example, the process chamber 100 may include an upper housing 101 in which the plasma generator 140 may be installed, and a lower housing 102 in which the base 110 and the substrate holder 200 may be arranged. The upper and the lower housings 101 and 102 may be combined with one other and an inner space of the combination of the upper and the lower housings 101 and 102 may be separated from surroundings and be prepared for the dry etching process such as a plasma etching process to the substrate therein. For example, when the upper and lower housings 101 and 102 are combined to form the process chamber 100, the interior of the process chamber 100 may be isolated from the exterior environment to prevent contamination during the dry etching process. Thus, the inner space formed by the combination of the upper and lower housings 101 and 102 may be provided as an etching space ES for the substrate W. The upper and the lower housings 101 and 102 may have sufficient strength and stiffness for the dry etching process, so that the dry etching process may be steadily performed in the process chamber 100.

A lower structure of the dry etching apparatus 1000 including the base 110 may be arranged at a lower portion of the process chamber 100.

For example, the substrate holder 200 may be positioned on the base 110 and a second power source P2 and a third power source P3 may be electrically connected through the base 110 to provide an electrical power to a lower electrode 212 and a heater (not shown), respectively. In addition, a temperature controller (not shown) and a coolant (not shown) for controlling the temperature of the substrate in the dry etching process may also be provided with the base 110.

Further, the driver 400 for driving the focus ring 300 may also be prepared inside the base 110, so that the driver 400 may be protected from etching plasma of the plasma etching process. For example, the driver 400 may be provided within a lower interior portion of the base 110 to protect the driver 400 from etching plasma.

A shielding wall 120 may extend from the base 110 and be connected to an inner sidewall of the lower housing 102. The shielding wall 120 may separate a discharge space DS from the etching space ES in the process chamber 100. The etching space ES may be under a vacuum pressure and a high temperature for performing the plasma etching process, while the discharge space DS may be under a room temperature and an atmospheric pressure for discharging byproducts and residual gases of the etching process. The etching space ES and the discharge space DS may be communicated through a plurality of discharge holes 121. In some embodiments, the difference in pressure between the etching space ES and the discharge space DS may cause the byproducts and residual gases to move from the etching space ES to the discharge space DS. The byproducts and residual gases may move from the etching space ES to the discharge space DS via the plurality of discharge holes 121. The byproducts and the residual gases of the etching process in the discharge space DS may be removed from the process chamber 100 by a control valve V and a discharge pump P.

The inside of process chamber 100 may be divided into the etching space ES under the vacuum state and high temperature and the discharging space DS under a room temperature and an atmospheric pressure, and the base 110 may be arranged in the discharging space DS. Since the driver 400 may be arranged inside the base 110, the driver 400 may also be protected from the etching plasma of the plasma etching process.

A temperature controller (not shown) may be provided with the dry etching apparatus 1000. The temperature controller may control the substrate temperature and the inner temperature of the process chamber to maintain a stable temperature during the plasma etching process. In addition, a discharge member (not shown) may also be provided with the dry etching apparatus 1000 to allow the byproducts and residual gases of the etching process may be efficiently removed from the process chamber 100.

An upper structure of the dry etching apparatus 1000 including the plasma generator 140 may be arranged at an upper portion of the process chamber 100. For example, an upper structure including the plasma generator 140 may be provided in upper housing 101.

A source supplier 130, which may be arranged outside of the process chamber 100, may supply source gases for the etching process into the plasma generator 140, and the source gases may be transformed into the etching plasma in the plasma space PS. Then, the etching plasma may be supplied into the etching space ES through shower holes H of a shower head 142. The plasma generator 140 may include an upper electrode 141 that may be connected to a first power P1 and the shower head 142 having a plurality of the shower holes H. The plasma space PS may be interposed between the upper electrode 141 and the shower head 142 and may be connected to the source supplier 130.

The plasma generator 140 at the upper portion of the process chamber 100 may face the substrate holder 200 at the lower portion of the process chamber 100, so that the etching plasma may be injected downwardly to an area over the substrate W that may be hold by the substrate holder 200. For example, the plurality of shower holes H of the shower head 142 that are included in the plasma generator 140 may face the substrate holder 200, allowing etching plasma to flow through the shower holes H into the etching space ES.

The etching plasma may include active ions or radicals of the source gases, and the thin layers (not shown) on the substrate W may be etched off by the etching plasma according to etching algorithms. For instance, the etching plasma may be uniformly focused to an area, which may be referred to as sheath area, over the substrate W by the focus ring 300, thereby forming a uniform etching plasma over the substrate W. Therefore, the thin layers may be uniformly etched off by the uniform etching plasma along a whole surface of the substrate W.

The substrate holder 200 may include a chuck body 210 arranged on the base 110 and having a lower electrode 212 to which a high frequency electrical power is applied, an insulating ring 220 enclosing the chuck body 210 on the base 110, and a securing chuck 230 arranged on the chuck body 210 and securing the substrate W. In some embodiments, the insulating ring 220 may surround a circumference of the chuck body.

The chuck body 210 may comprise a conductive material such as aluminum (Al) and may be shaped into a disk having a diameter larger than that of the securing chuck 230. The lower electrode 212 may be arranged at an inside of the chuck body 210. The second power P2 may be electrically connected to the lower electrode 212, and the second power P2 may supply a high frequency electrical power that may be applied to the lower electrode 212. Together with the upper electrode 141 of the plasma generator 140, the lower electrode 212 may generate an electric field in the process chamber 100. The source gases in the plasma space PS may be transformed into the etching plasma by the electric field.

For example, a first electrical power having a frequency of about 60 MHz may be applied to the upper electrode 141 by the first power P1 and a second electrical power having a frequency of about 2 MHz may be applied to the lower electrode 212 by the second power P2.

The insulating ring 220 may be arranged on the base 110 and may enclose the chuck body 210. An upper surface of the base 110 that may not be covered by the chuck body 210 may be covered by the insulating ring 220, so that the base 110 may be protected from the etching plasma in the etching space ES. For example, the insulating ring 220 may comprise an insulation material such as ceramics and quartz.

As will be further described, the connecting rod 420 of the driver 400 may comprise steel having a sufficient strength for supporting the focus ring 300. If the connecting rod 420 penetrates through the conductive chuck body 210, the high frequency electric power may also be applied to the connecting rod 420 from the second power P2, which may deteriorate the uniformity of the etching plasma in the etching space ES. For those reasons, the insulating ring 220 may be arranged around the conductive chuck body 210, and the connecting rod 420 may penetrate through the insulating ring 220 in such a way that the connecting rod 420 may be electrically insulated from the conductive chuck body 210.

The securing chuck 230 may be arranged on the chuck body 210 and may comprise insulation materials such as ceramics. In the present example embodiment, the securing chuck 230 may be shaped into a disk on the chuck body 210. Various securing members may be provided with the securing chuck 230 for securing the substrate W to the securing chuck 230.

In some embodiments, an electrostatic chuck (ESC) may be used to generate an electrostatic force that clamps the substrate W to the securing chuck 230. For example, the securing chuck 230 may include a pair of polyimide films (not shown) and a conductive film (not shown) interposed between the polyimide films, and the conductive film may be connected to a third power P3 such as, for example, a direct current power source. When a direct current is applied to the conductive film of the securing chuck 230, electric charges may accumulate in the polyimide films and an electrostatic force may be generated between the polyimide films. The substrate W may be secured to the securing chuck 230 by the electrostatic force.

While the present example embodiment discloses the electrostatic chuck (ESC) for securing the substrate W through the use of the electrostatic force, any other securing devices, such as, for example, a mechanical clamp, may also be used for securing the substrate W.

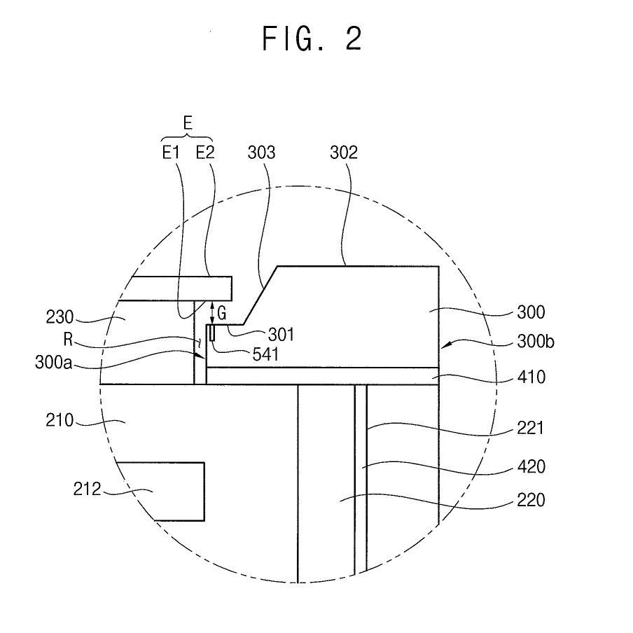

In some embodiments, the substrate W may have a diameter that is larger than a diameter of the securing chuck 230. Thus, the securing chuck 230 may be fully covered by the substrate W and an edge portion of the substrate W may be spaced apart from a sidewall 231 of the securing chuck 230. For example, the edge portion of the substrate W may be distanced away from the sidewall 231 of the securing chuck 230. The substrate W may be secured to the substrate holder 200 in such a way that a bottom surface of the substrate W that extends beyond the sidewall 231 of the securing chuck 230 may face an upper surface of the chuck body 210. Therefore, referring to FIG. 2, a recess R may be provided at a side of the securing chuck 230 in such a way that the recess R may be defined by the sidewall 231 of the securing chuck 230, the bottom surface of the substrate W and the upper surface of the chuck body 210.

An inner tip 300a of the focus ring 300 may be inserted into the recess R, so that the securing chuck 230 may be enclosed by the focus ring 300 and, as shown in FIG. 2, the edge portion E of the substrate W may be arranged over the inner tip 300a of the focus ring 300.

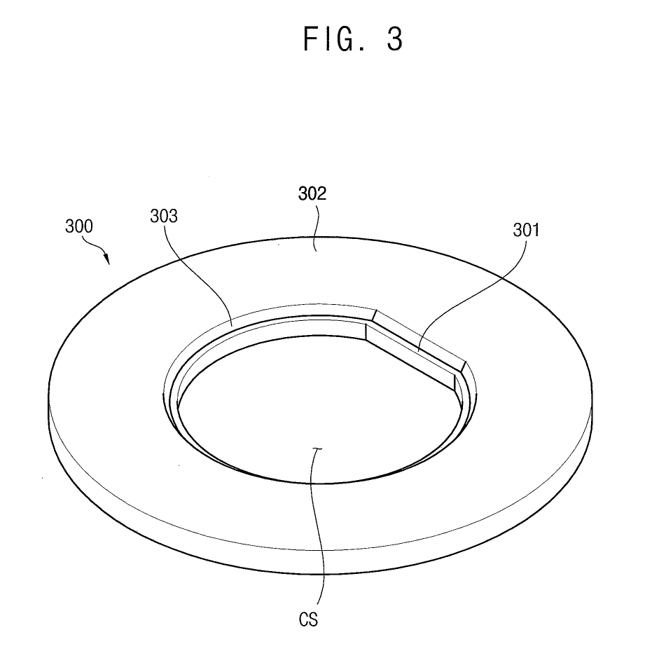

FIG. 2 is a cross-sectional view illustrating the substrate holder and the focus ring of the dry etching apparatus shown in FIG. 1, and FIG. 3 is a perspective view illustrating the focus ring shown in FIG. 2.

Referring to FIGS. 2 and 3, the securing chuck 230 may be positioned in a central space CS of the focus ring 300. The focus ring 300 may have a thickness sufficient to cover the chuck body 210 and the insulating ring 220.

For example, the focus ring 300 may include a lower top surface 301 that may be below the bottom surface E1 of the edge portion E of the substrate W, an upper top surface 302 that may be above a top surface E2 of the edge portion E of the substrate W, and a slant surface 303 connected to both of the lower top surface 301 and the upper top surface 302. The lower top surface 301 and the upper top surface 302 may be planar surfaces, and may be parallel to, and offset from, one another. The slant surface 303 may be formed at angle and extend from an edge of the lower top surface 301 to an edge of the upper top surface 302. Thus, the lower top surface 301 may be adjacent to the inner tip 300a of the focus ring 300, and the upper top surface 302 may be adjacent to an outer tip 300b that is opposite to the inner tip 300a of the focus ring 300. The substrate W and the focus ring 300 may be spaced apart from each other in the recess R by a gap distance G corresponding to a distance between the bottom surface E1 and the lower top surface 301.

The focus ring 300 may comprise conductive materials such as, for example, metal so that the active ions or the radicals of the etching plasma in the recess R may be driven to move above the edge portion E of the substrate W by the focus ring 300, thereby improving the uniformity of the etching plasma at the sheath area over the substrate W. For example, the etching plasma may be focused to the sheath area over the substrate W at high uniformity.

While the present example embodiment discloses a metal bulk-type focus ring, the focus ring 300 may be provided as an assembly including a conductive inner ring that may be close to the securing chuck 230 and an outer ring that may enclose the inner ring in a structural view of the dry etching apparatus 1000.

The lower top surface 301 and the upper top surface 302 of the focus ring 300 may be gradually etched off by the etching plasma in the dry etching process, so that the lower top surface 301 and the upper top surface 302 may be lowered gradually as the plasma etching process progresses. As a result, the gap distance G between the substrate W and the focus ring 300 may increase and a larger amount of the etching plasma may be gathered in the recess R, which may deteriorate the uniformity of the etching plasma at the sheath area over the substrate W. The uniformity deterioration of the etching plasma may cause etching defects to the pattern structures, particularly, at the edge portion E of the substrate W.

In some embodiments, when etching defects are found in the pattern structures, the focus ring 300 may be automatically lifted upwards to reduce the gap distance G between bottom surface of the substrate W and the lower top surface 301 of the focus ring 300. For example, although the height of the focus ring 300 may be reduced as the plasma etching process progresses in the process chamber 100, the focus ring 300 may automatically move upwards in such a way that the gap distance G may be substantially unchanged. Thus, the etching plasma may be evenly distributed over the substrate W and the etching process may be uniformly performed on the whole surface of the substrate W.

As shown in FIGS. 1 and 2, the driver 400 may include a support plate 410 supporting the focus ring 300, a connecting rod 420 connected to the support plate 410 and moving the support plate 410 upwards and downwards in the vertical direction, a driving shaft 430 driving the connecting rod 420, and a power source 440 generating a driving power for driving the connecting rod 420. For example, the power source 440 may generate driving power that drives the connecting rod 420 to move the support plate 410 in up and down directions relative to the bottom surface E1 of the edge portion E.

The support plate 410 may be shaped as a ring and interposed between a bottom surface of the focus ring 300 and upper surfaces of the chuck body 210 and the insulating ring 220. The support plate 410 may include a single disk substantially having the shape of the focus ring 300 or the support plate 410 may include a plurality of plate pieces that may be assembled to form the ring. The support plate 410 may comprise insulating materials so that the focus ring 300 and the chuck body 210 may be electrically separated from each other by the support plate 410.

The connecting rod 420 may be connected to the support plate 410 through the insulating ring 220 and may extend to an inside of the base 110, and the driving shaft 430 may be connected to the connecting rod 420 and the power source 440 in the base 110.

The connecting rod 420 may include a slender member extending downwards from the support plate 410 and penetrating through the insulating ring 220. An upper end of the connecting rod 420 may support the support plate 410 and the focus ring 300, and a lower end of the connecting rod 420 may be connected to the driving shaft 430 in the base 110. Thus, the connecting rod 420 may comprise a rigid material having a sufficient strength for supporting the support plate 410 and the focus ring 300.

In the present example embodiment, the connecting rod 420 may include three slender members that may be arranged in the vertical direction symmetrically with one another at an angle of about 120°. For example, each slender member of the connecting rods 420 may be uniformly distributed along a circumference of a circle for which the central axis of the substrate holder 200 is the center (e.g., at 0°, 120°, and 240°), and may be substantially perpendicular to the substrate holder 200 and parallel to the central axis. Thus, the focus ring 300 may be supported at three contact points with uniform supporting force from the three slender members. The number and arrangements of the connecting rod 420 may be varied as long as the focus ring 300 may be stably supported by the connecting rod 420. For example, the connecting rod 420 may include four slender members that are positioned around the central axis of the substrate holder 200 at 0°, 90°, 180°, and 270°, or the connecting rod 420 may include five slender members that are positioned around the central axis of the substrate holder 200 at 0°, 72°, 144°, 216°, and 288°, or the connecting rod 420 may include six slender members that are positioned around the central axis of the substrate holder 200 at 0°, 60°, 120°, 180°, 240°, and 300°, etc.

A sealing member 450, such as, for example, an O-ring, may be installed at a boundary surface of the connecting rod 420 and the base 110. Since the insulating ring 220 may include a penetration hole 221 through which the connecting rod 420 may extend to the inside of the base 110, the etching space ES may be fluidly connected with the inside of the base 110, allowing fluids to move through the penetration hole 221. Thus, the process conditions of the plasma etching process may be deteriorated by the leakage through the penetration hole 221. For example, the vacuum pressure of the etching space ES may be reduced by an inflow of air through the penetration hole 221 of the insulating ring 220. The sealing member 450 around the connecting rod 420 on the base 110 may protect the leakage through the penetration hole 221, and thus the process conditions in the etching space ES may be sufficiently maintained in the etching process. For example, the sealing member 450 may facilitate maintenance of a desired vacuum pressure of the etching space ES.

A leveler 460 for controlling a level degree of the connecting rod 420 may be further provided with the driver 400. Thus, the connecting rod 420 may be connected to the support plate 410 in a horizontal state with respect to the base 110, so that the support plate 410 may move upwards and downwards horizontally with respect to the upper surface of the base 110. If the connecting rod 420 is slanted with respect to the base 110, the connecting rod 420 may be obliquely connected to the support plate 410 and the vertical moving distance of the support plate 410 may be varied at each contact point of the connecting rod 420, which may cause the failure of the combination between the connecting rod 420 and the support plate 410. In addition, the variation of the vertical moving distance of the support 410 may cause the collision of the substrate W to the lower top surface 301 of the focus ring 300. Therefore, the leveler 460 may force the connecting rod 420 to be horizontal with respect to the upper surface of the base 110 and may force the support plate 410 and the focus ring 300 to move in the vertical direction horizontally with respect to the base 110, thereby sufficiently preventing the interference between the substrate W and the focus ring 300. In some embodiments, the leveler 460 may force each slender member of the connecting rod 420 to be horizontal to the upper surface of the base 110, ensuring that the support plate 410 and the focus ring 300 move in the vertical direction in a uniform manner with respect to the base 110.

The driving shaft 430 may transfer the driving force to the connecting rod 420 from the power source 440, and the connecting rod 420 may move upwards and downwards by the driving force. In an example embodiment, the driving shaft 430 may rotate on a central axis thereof by the power source 440, and the connecting rod 420 may move linearly according to the rotation of the driving shaft 430.

The power source 440 may generate a sufficient driving power for driving the support plate 410 and the focus ring 300. For example, the power source 440 may include an electric motor or a hydraulic motor sufficient to account for the total weight of the focus ring 300 and the support plate 410 and control characteristics of the power source 440. In the present example embodiment, the power source 440 may include a servo motor having excellent control characteristics to control position of the focus ring 300 and support plate 410.

The driver 400 may be selectively operated by the position controller 500 according to inspection results of the pattern structures that may be formed on the substrate W by the plasma etching process. For example, when the inspection data of the pattern structures indicates a deviation from an allowable range or value, the position controller 500 may control the driver 400 to move the focus ring 300 upwards to thereby increase the uniformity of the etching plasma over the substrate W. For example, when the inspection data indicates process defects of the pattern structures, the position of the focus ring 300 may be automatically controlled in the process chamber 100 to thereby minimize the process defects and increase the yield of semiconductor devices, particularly, the yield of semiconductor devices at the edge portion of the substrate W.

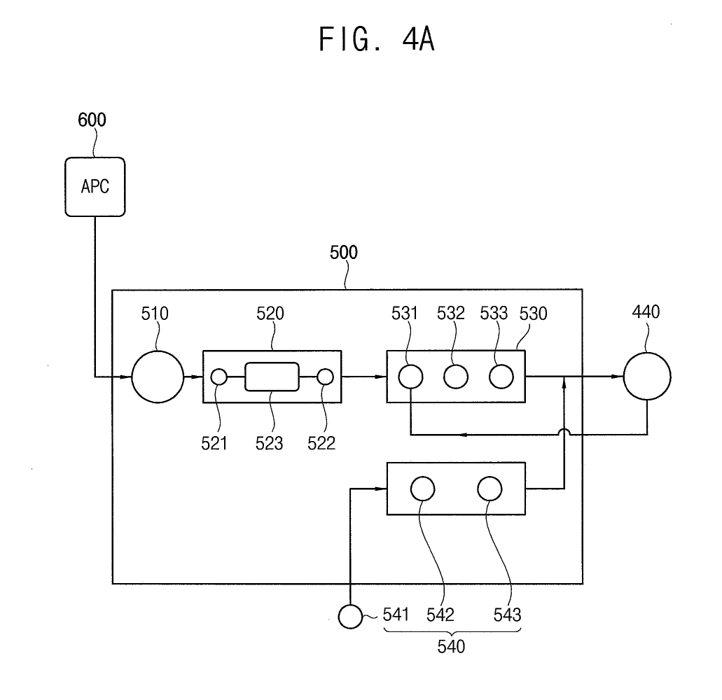

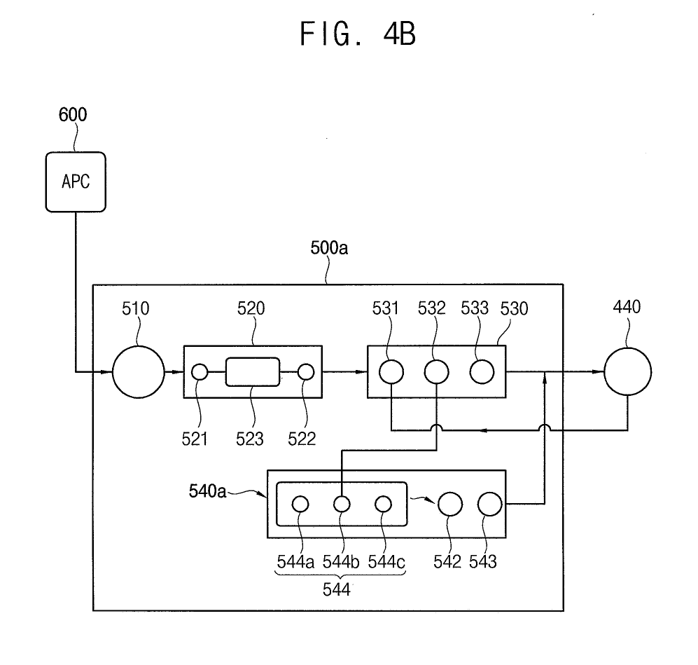

FIG. 4A is a block diagram showing the position controller of the dry etching apparatus shown in FIG. 1.

Referring to FIG. 4A, the position controller 500 may include a data port 510 obtaining inspection data from the inspection results of the pattern structures, a position signal generator 520 generating a position signal including a correct position of the focus ring 300 when the inspection data is deviated from reference data, and a driving signal generator 530 generating a driving signal for driving the focus ring 300 to move to the correct position.

For example, some of the pattern structures may be inspected by an additional inspection process and the inspection results may be stored into an additional memory device (not shown) at every inspected substrate W. In the present example embodiment, a dummy pattern structure may be additionally formed at an inspection area of the substrate W together with cell pattern structures at a cell area of the substrate W and the dummy pattern structures may be inspected based on given inspection items. The inspection items may include, for example, a composition of the pattern structure, a line width of each pattern structure and an etching depth of the pattern structure. The inspected compositions, line widths, and the etching depths of each pattern structure may be stored in the memory device as inspection data, and the inspection data with respect to each substrate W may be accumulated as an inspection database of the pattern structures of the dry etching process.

The data port 510 may be connected to the inspection database and the inspection data may be transferred to the data port 510 in real-time with the inspection process. For example, the data port 510 may include a wire port that may be connected to the inspection database by using a local area network (LAN) line or a wireless port that may be connected to the inspection database by using a wireless communication network such as a Wi-Fi network.

The position signal generator 520 may include a buffer 521 that may be connected to the data port 510 and receive the inspection data from the inspection database, a reference setup unit 522 for setting up reference data corresponding to each of the inspection items, and a first signal generator 523 comparing the inspection data and the reference data and generating a position signal having a correct position of the focus ring 300. The position signal may be generated when the inspection data deviates from an allowable range or value of the reference data. For example, the first signal generator 523 may generate the position signal when the inspection data includes data that exceeds allowable values or ranges of values.

The reference setup unit 522 may include one or more input devices, such as, for example, a keyboard and a touch pad, and a reference memory for storing the reference data. The reference data may include, for example, optimal data for the line width, etching depth, composition of the pattern structure, etc. In the present example embodiment, the reference data may include expected minimal values of the line width(s) and etching depth(s) of the pattern structure.

While the present example embodiment illustrates the reference setup unit 522 provided with the position controller 500, the reference setup unit 522 may also be provided with the automatic process controller 600 in place of the position controller 500. In such a case, the reference data may be transferred to the buffer 521 together with the inspection data.

The first signal generator 523 may be connected to the buffer 521 and the reference setup unit 522 and may call the inspection data and the reference data. For example, the first signal generator 523 may request and receive the inspection data and the reference data from the buffer 521 and reference setup unit 522. Then, the inspection data may be compared with the reference data. When the inspection data deviates from the reference data, the position signal for changing the position of the focus ring 300 may be generated from the first signal generator 523. For example, if the first signal generator 523 compares the inspection data with the reference data and determines deviations between the data, the first signal generator 523 may generate the position signal to change the position of the focus ring 300.

For example, when the line width of the pattern structure is smaller than the reference line width, the first signal generator 523 may generate the position signal for moving up the focus ring 300 closer to the substrate W. The inspection data may be transferred to the first signal generator 523 and may be compared with the reference data whenever the inspection process is performed with respect to the pattern structures. When the deviation between the inspection data and the reference data is within the allowable range, the dry etching process may still be performed at the current position of the focus ring 300. In contrast, when the deviation between the inspection data and the reference data is outside of the allowable range, the dry etching process may be stopped and the position of the focus ring 300 may be changed to thereby increase the uniformity of the etching plasma.

The inspection items of various pattern structures may be accumulated in the database in relation with the focus ring position for the etching plasma by which the pattern structure was formed. For example, the database may store reference data corresponding to the inspection items of various pattern structures (e.g., a composition of the pattern structure, a line width of each pattern structure and an etching depth of the pattern structure) for each focus ring position. Thus, the focus ring position corresponding to the reference data may be selected from the database as the correct position of the focus ring 300 when the deviation between the inspection data and the reference data is outside of the allowable range. For example, the correct position of the focus ring 300 may include a position of the lower top surface 301 and a position of the upper top surface 302. The first signal generator 523 may generate the position signal together with the correct position. For example, the position signal may be generated as a pulse signal.

The driving signal generator 530 may generate the driving signal for driving the focus ring 300 to move to the correct position in response to the position signal transferred from the position signal generator 520.

For example, the driving signal generator 530 may include an encoder 531 detecting a current position of the focus ring 300, a distance calculator 532 calculating a correct distance corresponding to a position difference between the current position and the correct position, and a second signal generator 533 generating a power signal that may be applied to the power source and drive the connecting rod 420 to move in the vertical direction by the correct distance. For example, the second signal generator may generate a power signal that is applied to the power source to drive the connecting rod 420 to move to the correct position.

The encoder 531 may be connected to the driver 400 and may determine the position of the connecting rod 420. Then, the encoder 531 may obtain the current position of the focus ring 300 from the position of the connecting rod 420. For example, the power source 440 of the driver 400 may include a servo motor for accurately controlling the position of the connecting rod 420, and the encoder 531 may obtain the position and motion information of the connecting rod 420 from the operation information of the servo motor. Thus, the position of the focus ring 300 may be directly calculated from the position and motion information of the connecting rod 420.

The distance calculator 532 may compare the current position and the correct position of the focus ring 300, and calculate the position difference between the current position and the correct position. Then, the distance calculator 532 may generate the correct distance corresponding to the position difference. For example, the distance calculator 532 may generate the correct distance to which the focus ring 300 is to be moved in order to be in the correct position.

The correct distance may be transferred to the second signal generator 533, and the second signal generator 533 may generate the power signal that may be applied to the power source 440. Thus, the driving signal may be transferred to the power source by the second signal generator 533 as the power signal. The power source 440 may operate in response to the driving signal in such a way that the drive connecting rod 420 may be moved in the vertical direction by the correct distance and move the focus ring 300 to the correct position. For example, the driving signal may be generated as a pulse signal.

The power source 440 may be selectively operated in accordance with the deviation between the inspection data and the reference data, and the focus ring 300 may automatically move to the correct position when the deviation may be out of the allowable range or exceeds an allowable threshold value.

The position controller 500 may further include a stopper 540 for stopping the focus ring 300 as it moves upwards to thereby prevent the contact of the lower top surface 301 of the focus ring 300 and the bottom surface E1 of the edge portion E of the substrate W.

For example, the stopper 540 may include a gap detector 541 for detecting a gap distance G in the vertical direction between the lower top surface 301 of the focus ring 300 and the bottom surface E1 of the substrate W, a stopping signal generator 542 for generating a stopping signal for stopping the focus ring 300 from moving upwards when the gap distance G may be smaller than a minimal gap distance, and a destructive signal generator 543 generating a destructive signal for cancelling the driving signal by a destructive interference in response to the stopping signal. Stopping the focus ring 300 may include preventing the start of a movement of the focus ring 300 and/or discontinuing an ongoing movement of the focus ring 300.

The gap detector 541 may include an optical sensor (not shown) that may be buried on the lower top surface 301 of the focus ring 300 at a location that is vertically opposite to the bottom surface E1 of the substrate W. A measuring beam may be radiated to the bottom surface E1 from the optical sensor, and a reflective beam reflected from the bottom surface E1 of the substrate W may be detected by the optical sensor. The gap detector 541 may calculate the gap distance G between the bottom surface E1 and the lower top surface 301 using the reflective beam. The detected gap distance G may be transferred to the stopping signal generator 542 by a wired and/or a wireless communication member.

The stopping signal generator 542 may include a gap buffer (not shown) for storing the detected gap distance G an input device (not shown) for inputting a minimal gap distance, and a processor (not shown) for comparing the detected gap distance and the minimal gap distance and generating the stopping signal.

When the detected gap distance is smaller than the minimal gap distance, the processor of the stopping signal generator 542 may generate the stopping signal for stopping the movement of the focus ring 300. The stopping signal may be transferred to the destructive signal generator 543.

The destructive signal generator 543 may generate the destructive signal that may be combined with the driving signal in the destructive interference mode. The destructive signal may be combined with the driving signal before the driving signal is applied to the power source 440. Therefore, in some embodiments, the driving signal may be canceled by the destructive interference, and the power source 440 may not be operated. In such a case, the focus ring 300 may be located at the same current position. For example, when the destructive interference created by the destructive signal cancels the driving signal, the focus ring 300 may not move, but may remain in its current position.

When the inspection data deviates from the reference data and simultaneously when the destructive signal occurs, the dry etching process may be stopped and the focus ring 300 may be replaced with new one. For example, when the destructive signal occurs, canceling out the driving signal at the same time that the inspection data identifies a deviation from the reference data, it may indicate that the focus ring is to be replaced. Thus, the dry etching process may be stopped.

While the present example embodiment discloses that the movement of the focus ring may be stopped based on comparisons between the detected gap distance and the minimal gap distance, a calculated gap distance may also be used for stopping the movement of the focus ring 300. The calculated gap distance may be determined automatically on a real-time basis during the movement of the focus ring 300.

FIG. 4B is a block diagram showing a modification of the position controller shown in FIG. 4A. In FIG. 4B, the modified position controller 500a may have substantially the same structures as the position controller 500 in FIG. 4A, except for a modified stopper 540a. Thus, in FIG. 4B, the same reference numerals denote the same elements in FIG. 4A and the detailed descriptions of the same elements will be omitted.

Referring to FIG. 4B, the modified position controller 500a may include a modified stopper 540a and may stop the upward movement of the focus ring 300 not by the detected gap distance but by a calculated gap distance.

For example, the modified stopper 540a may include a gap calculator 544 for calculating a gap distance in the vertical direction. The gap calculator may calculate the gap distance by subtracting a moving distance of the focus ring 300 to the correct position from an initial gap distance between the lower top surface 301 of the focus ring 300 and the bottom surface E1 of the substrate W at an initial time of the etching process. The modified stopper 540a may also include the stopping signal generator 542 and the destructive signal generator 543. The stopping signal generator 542 and the destructive signal generator 543 of the modified stopper 540a may have the same structures as those of the stopper 540 of FIG. 4A.

The gap calculator 544 may include a first buffer 544a storing the initial gap distance between the substrate W and the focus ring 300 at a time when the dry etching process is initiated, a second buffer 544b storing the correct distance of the focus ring 300 received from the distance calculator 532, and an arithmetic processor 544c for subtracting the correct distance from the initial gap distance and obtaining an instantaneous gap distance at the moment when the focus ring 300 moves upwards.

Thus, the initial gap distance may be a maximal gap distance between the bottom surface E1 and the lower top surface 301, and the gap distance G may be reduced whenever the focus ring 300 moves during the etching process. The gap distance G between the substrate W and the focus ring 300 may be automatically calculated whenever the focus ring 300 moves in the vertical direction. The calculated gap distance G may be transferred to the stopping signal generator 542 by a wired or a wireless communication member.

The stopping signal generator 542 may include a gap buffer (not shown) for storing the calculated gap distance G an input device (not shown) for inputting a minimal gap distance, and a processor (not shown) for comparing the calculated gap distance G and the minimal gap distance and generating the stopping signal.

When the calculated gap distance is smaller than the minimal gap distance, the processor of the stopping signal generator 542 may generate the stopping signal for stopping the movement of the focus ring 300. The stopping signal may be transferred to the destructive signal generator 543.

The destructive signal generator 543 may generate the destructive signal that may be combined with the driving signal in the destructive interference mode. In some embodiments, the driving signal may be canceled by the destructive interference, and the power source 440 may not be operated. In such a case, the focus ring 300 may be located at the same current position. For example, when the destructive interference created by the destructive signal cancels the driving signal, the focus ring 300 may not move, but may remain in its current position.

While the present example embodiment discloses that the initial gap distance is stored in the gap calculator 544, the initial gap distance may be provided with a control loop for driving the focus ring 300 in various ways.

For example, the initial gap distance may be stored in the automatic process controller (APC) 600, and the initial gap distance may be transferred to the data port 510 together with the inspection data from the APC 600. The initial gap distance may be predetermined and stored in the APC 600 or the initial gap distance may be previously determined and stored in the APC 600.

In addition, while the present example embodiment discloses that the driving signal may be canceled through the destructive interference between the driving signal and the destructive signal, various methods and techniques may be allowable as well as, or in place of, the destructive interference as long as the movement of the focus ring 300 may be stopped.

The position controller 500 may be connected to the APC 600, which may be arranged at an outside of the process chamber 100 as illustrated in FIG. 1, and may have process control algorithms for controlling the dry etching process applied to the substrate W. In some embodiments, the position controller 500 may be a part or a portion of an etch control logic of the APC 600.

The APC 600 may control an overall etching process to the substrate W. For example, the APC 600 may control an object substrate W, which may be etched in the process chamber 100, by causing the substrate W to be drawn into the process chamber 100 using a substrate transfer, such as a front opening universal pod (FOUP). Then, a series of processes including an etching process, a cleaning process, and a dry process may be sequentially performed on the object substrate W to thereby form the pattern structures on the object substrate W under the control of the APC 600. For example, the APC 600 may control every process step for forming pattern structures on the substrate W under preset algorithms.

The APC 600 may be arranged at an outside of a substrate treating system having a substrate loader, a transfer robot, an etching chamber, a cleaning chamber and a dry chamber, and the APC 600 may control a series of treating processes performed on the substrate W under the process algorithms. For example, the APC 600 may include a central control center 610, a computer system 620, and a data server 630.

In the present example embodiment, the inspection data corresponding to the pattern structures may be accumulated and stored in the data server 630 as an inspection database, and the inspection database may be connected to the data port 410 of the position controller 400. For example, the inspection data may be transmitted and/or received via the data port 410 of the position controller 400.

The focus ring 300 may automatically move upwards in relation to the inspection data of the pattern structure, so that the uniformity of the etching plasma may be automatically controlled according to the inspection data of the pattern structures.

The above dry etching apparatus 1000 may be operated as follows.

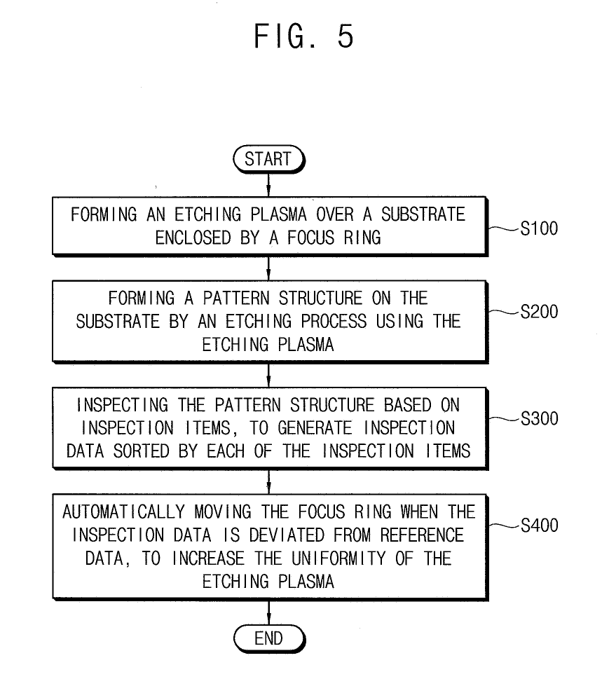

FIG. 5 is a flow chart of an exemplary process for etching a substrate using the exemplary dry etching apparatus shown in FIG. 1. The dry etching apparatus may be used to perform a dry etching process at any point during the semiconductor manufacturing process, and may be repeated throughout the semiconductor manufacturing process. For example, the dry etching process may be performed on a clean substrate, and then repeated after one or more layers have been applied to, or formed on, the substrate. Based on the disclosed embodiments and one or more other processes, a semiconductor device, such as an integrated circuit semiconductor chip, may be formed.

Referring to FIGS. 1 and 5, a uniform etching plasma may be formed at a sheath area over the substrate W enclosed by a focus ring 300 (step S100).

Source gases may be supplied to the plasma generator 140 from the source supplier 130 which may be arranged outside of the process chamber 100, and then the source gases may be transformed into the etching plasma in the plasma space PS by an electric field between the upper electrode 141 and the lower electrode 212. Then, the etching plasma may be supplied into the etching space ES through shower holes H of a shower head 142. The plasma generator 140 at the upper portion of the process chamber 100 may face the substrate holder 200 at the lower portion of the process chamber 100, so that the etching plasma may be injected downwardly to an area over the substrate W that may be held by the substrate holder 200. The etching plasma may include active ions or radicals of the source gases, and the thin layers on the substrate W may be etched off by the etching plasma according to etching algorithms.

Next, the pattern structures may be formed uniformly on the substrate W by a plasma etching process using the etching plasma (step S200).

The etching plasma, including the active ions and the radicals, may be uniformly focused to the sheath area over the substrate W by the focus ring 300, thereby forming a uniform etching plasma over the substrate W. Therefore, the thin layers may be uniformly etched off by the uniform etching plasma along a whole surface of the substrate W.

The substrate W may be secured to the securing chuck 230 of the substrate holder 200, and the securing chuck 230 may be positioned in a central space CS of the focus ring 300. Therefore, the focus ring 300 may enclose the securing chuck 230, and the substrate W may be positioned at a central portion of the focus ring 300.

The active ions and the radicals of the etching plasma may be focused at the central portion of the focus ring 300. Thus, the etching plasma may be uniformly distributed on the sheath area over the substrate W in the etching space ES of the process chamber 100.

The thin layer on the substrate W may be sequentially etched off by the etching plasma according to the preset etching algorithms, thereby forming the pattern structures on the substrate W.

Then, the pattern structures may be inspected by various inspection processes. The inspection results may be sorted and stored by inspection items in the inspection database, to thereby generate the inspection data (step S300). For example, the inspection database may store inspection results corresponding to each inspection item.

Some of the pattern structures may be inspected by an additional inspection process, and the inspection results may be stored into an additional memory device at every inspected substrate W. Additionally, dummy pattern structures may be formed at an inspection area of the substrate W together with cell pattern structures at a cell area of the substrate W, and the dummy pattern structures may be inspected based on given inspection items. The inspection items may include a composition of the pattern structure, a line width of each pattern structure, and an etching depth of the pattern structure. The inspected compositions, line widths, and etching depths of each pattern structure may be stored in the memory device as inspection data, and the inspection data with respect to each substrate W may be accumulated as an inspection database of the pattern structures of the dry etching process.

For example, the inspection database may be stored in a memory of the server 630 of the APC 600. In the present example embodiment, the line widths of the pattern structure may be selected by the criteria for determining the etching defect of the pattern structure.

The lower and upper surfaces 301 and 302 of the focus ring 300 may also be etched off by the etching plasma in the plasma etching process, and the gap distance G between the lower top surface 301 of the focus ring 300 and the bottom surface E1 of the substrate W may gradually increase as the plasma etching process progresses. The increase of the gap distance G between the substrate W and the focus ring 300 may cause deterioration of the uniformity of the etching plasma at the sheath area and may cause etching defects of the pattern structures at the edge portion E of the substrate W. As a result, the line widths of the pattern structures at the edge portion E of the substrate W may be sufficiently deviated from the reference values or range of values.

When the etching defects (e.g., deviated line widths) are found in the pattern structures, the focus ring 300 may be automatically lifted upwards, reducing the gap distance G between the bottom surface E1 of the substrate W and the lower top surface 301 of the focus ring 300, to thereby increase or maintain the uniformity of the etching plasma across the whole surface of the substrate W (step S400). For example, although the height of the focus ring 300 may be reduced as the plasma etching process progresses in the process chamber 100, the focus ring 300 may automatically move upwards in such a way that the gap distance G may be substantially unchanged. Thus, despite the height reduction of the focus ring 300, the uniformity of the etching plasma may be substantially unchanged or may increase so that the plasma etching process is uniformly performed on the whole surface of the substrate W.

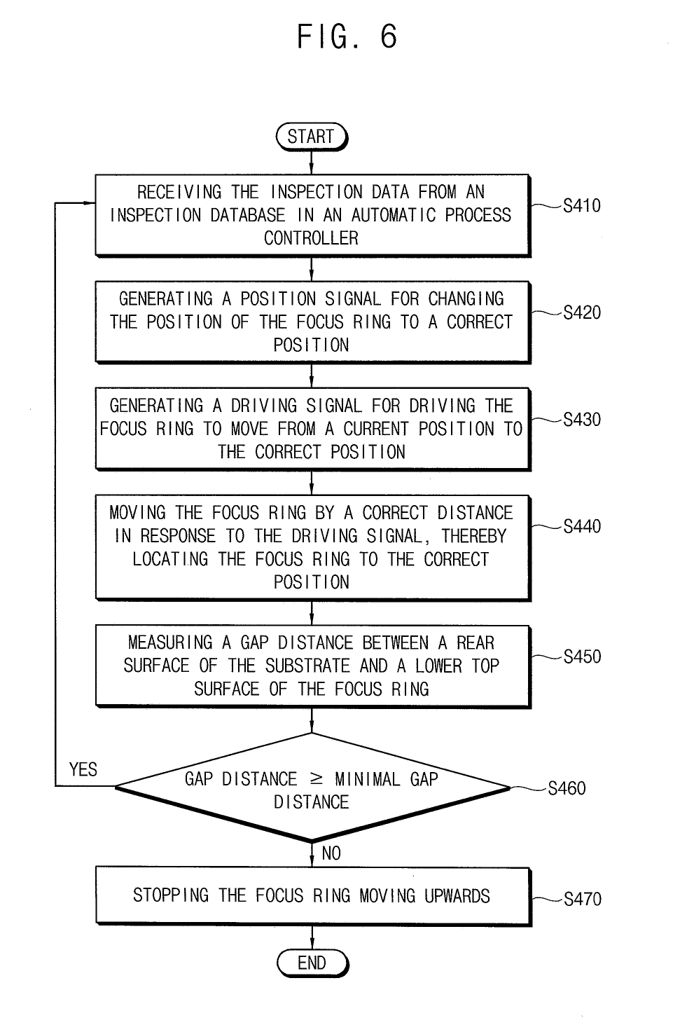

FIG. 6 is a flow chart of an exemplary process for automatically moving the focus ring upwards, as discussed in connection with the flowchart of FIG. 5.

Referring to FIG. 6, the inspection data may be transferred to the data port 510 of the position controller 500 from the inspection database in the APC 600 (step S410). The inspection data may be transmitted and/or received via a wired or a wireless communication system. The position signal generator 520 may compare the inspection data with the reference data.

Then, when the inspection data is determined to deviate from the reference data, the position signal for changing the position of the focus ring 300 may be generated from the first signal generator 523 (step S420).

In the present example embodiment, when the line width of the pattern structure is smaller than the reference line width, the first signal generator 523 may generate the position signal for moving up the focus ring 300. For example, the first signal generator 523 may generate a position signal causing the focus ring 300 to move in a direction toward the bottom surface E1 of the substrate W. The inspection data may be transferred to the first signal generator 523 and compared with the reference data whenever the inspection process is performed in connection with the pattern structures. When the deviation between the inspection data and the reference data is within the allowable range, the dry etching process may still be performed at the current position of the focus ring 300. For example, when the deviation is within the allowable range, the position of the focus ring 300 may remain unchanged and the dry etching process may continue. In contrast, when the deviation between the inspection data and the reference data is outside of the allowable range, the dry etching process may be stopped and the position of the focus ring 300 may be changed to maintain or increase the uniformity of the etching plasma.

In exemplary embodiments, the inspection items of various pattern structures are accumulated and stored in the database in relation with the focus ring position for the etching plasma by which the pattern structure was formed. Thus, the focus ring position corresponding to the reference data may be selected as the correct position of the focus ring 300 when the deviation between the inspection data and the reference data is outside of the allowable range. For example, the correct position of the focus ring 300 may include a position of the lower top surface 301 and a position of the upper top surface 302. The first signal generator 523 may generate the position signal together with the correct position. For example, the position signal may be generated as a pulse signal.

Then, a driving signal may be generated from the driving signal generator 530, and the focus ring 300 may move to the correct position from the current position (step S430). In some embodiments, the driving signal generator 520 may generate a driving signal that causes the focus ring 300 to move from the current position to the correct position based on the deviation between the inspection data and the reference data.

For example, the encoder 531, which may be connected to the driver 400, may obtain the current position of the focus ring 300 from the position of the connecting rod 420. The power source 440 of the driver 400 may include a servo motor for accurately controlling the position of the connecting rod 420, and the encoder 531 may obtain the position and motion information of the connecting rod 420 from the operation information of the servo motor. In some embodiments, the position of the focus ring 300 may be calculated from the position and motion information of the connecting rod 420. The distance calculator 532 may compare the current position with the correct position of the focus ring 300, and calculate the position difference between the current position and the correct position. Then, the distance calculator 532 may calculate the correct distance corresponding to the position difference. For example, the distance calculator 532 may calculate the correct distance that the focus ring 300 is to be moved.

The correct distance may be transferred to the second signal generator 533, and the second signal generator 533 may generate the power signal that may be applied to the power source 440. Thus, the driving signal may be transferred to the power source by the driving signal generator 530 as the power signal. For example, the driving signal may be generated as a pulse signal.

Then, the driver 400 may drive the focus ring 300 to move upwards by a correct distance in response to the driving signal, thereby locating the focus ring to the correct position (step S440).

The power source 440 of the driver 400 may operate in response to the driving signal in such a way that the drive connecting rod 420 may be moved in the vertical direction by the correct distance and move the focus ring 300 to the correct position. For example, the power source 440 may be selectively operated based on the deviation between the inspection data and the reference data, and the focus ring 300 may automatically move to the correct position when the deviation is outside of the allowable range or exceeds an allowable threshold value.

Then, the gap distance G between the bottom surface E1 of the substrate W and the lower top surface 301 of the focus ring 300 may be measured by the gap detector 541 or the gap calculator 544 (step S450).

When the focus ring 300 moves upwards until the gap distance G disappears and the bottom surface E1 of the edge portion E of the substrate W makes direct contact with the lower top surface 301 of the focus ring 300, the plasma sheath over the substrate W may be destroyed. Thus, the gap distance G may need to be larger than the minimal gap distance between the substrate W and the focus ring 300. For that reason, in some embodiments, when the gap distance G is measured and determined to be smaller than the minimal gap distance, the upward movement of the focus ring 300 may be automatically stopped by the stopper 540. Stopping the focus ring 300 may include preventing the start of a movement of the focus ring 300 and/or discontinuing an ongoing movement of the focus ring 300.

The gap distance G may be detected using the gap detector 541 or may be calculated by the gap calculator 544. For example, in some embodiments, a measuring beam may be radiated to the bottom surface E1 from the optical sensor (not shown), which may be buried on the lower top surface 301 of the focus ring 300 at a location that is vertically opposite to the bottom surface E1 of the substrate W, and a reflective beam reflected from the bottom surface E1 of the substrate W may be detected by the optical sensor. The gap detector 541 may calculate the gap distance G between the bottom surface E1 and the lower top surface 301 using the reflective beam. In other embodiments, the gap distance G between the substrate W and the focus ring 300 may be automatically calculated whenever the focus ring 300 moves in the vertical direction, such that the correct distance of the focus ring 300 may be the difference between the initial gap distance (e.g., a maximal gap distance between the rear surface E1 and the lower top surface 301) and the gap distance G. The calculated or the detected gap distance G may be transferred to the stopping signal generator 542 by a wire and/or a wireless communication member.

The measured gap distance G may be compared with the minimal gap distance (step S460) in the processor of the stopping signal generator 542. When the measured gap distance G is larger than the minimal gap distance, the stopping signal may not be generated and the focus ring 300 may be moved to the correct position. In contrast, when the measured gap distance G is smaller than the minimal gap distance, the processor of the stopping signal generator 542 may generate the stopping signal for stopping the movement of the focus ring 300 (step S470). In such a case, the plasma etching process may also be stopped in the process chamber 100.

In some embodiments, when the measured gap distance G is smaller than the minimal gap distance, the focus ring 300 may move upwards to a maximal point in the process chamber 100. Thus, the dry etching apparatus 1000 may be completely stopped and the focus ring 300 may be replaced with a new one.

The stopping signal may be transferred to the destructive signal generator 543. The destructive signal generator 543 may generate a destructive signal that may be combined with the driving signal in the destructive interference mode. The destructive signal may be combined with the driving signal before the driving signal is applied to the power source 440. Therefore, the driving signal may be canceled by the destructive interference, and the power source 440 may not be operated. For example, when the destructive interference created by the destructive signal cancels the driving signal, the focus ring 300 may not move, but may remain in its current position.

As illustrated in the exemplary flowcharts of FIGS. 5 and 6, a plasma etching process may be used to form fine patterns for semiconductor devices. For example, source gases may be transformed into source plasma in the process chamber and guided onto the substrate on an electrostatic chuck (ESC) by a focus ring. The substrate itself, or layers on the substrate (e.g., a layer directly on the substrate and/or layers above other layers on the substrate), may be etched off by the active ions or radicals in the source plasma. During the etching process, inspection items may be inspected to determine if a height of the focus ring is reduced. When it is determined that the focus ring is deteriorated (e.g., the height is reduced), the focus ring is raised up to thereby maintain a consistent gap distance G.

In some embodiments, the inspection process may be performed between plasma etching processes. For example, when a plasma etching process is completed for a first substrate, an inspection process may be performed on the first substrate. If it is determined that the focus ring is deteriorated (e.g., the height is reduced), the focus ring may be raised up and another plasma etching process may be performed on, for example, the same substrate and/or another substrate. In still other embodiments, the inspection process may be performed during a single plasma etching process. For example, during the course of a single plasma etching process, an inspection process may be performed on the substrate. If it is determined that the focus ring is deteriorated (e.g., the height is reduced), the focus ring may be raised up and the same plasma etching process may continue on the substrate. Based on the disclosed embodiments and one or more other processes, a semiconductor device, such as an integrated circuit semiconductor chip, may be formed.

According to the example embodiments of the dry etching apparatus and the method of etching the substrate using the dry etching apparatus, the focus ring 300 may be automatically moved upwards to the correct position based on the inspection results of the pattern structures on the substrate W. Although the height of the focus ring may be reduced as the plasma etching process progresses in the process chamber 100, the focus ring may automatically move upwards in such a way that the gap distance may be substantially unchanged. Thus, the uniformity of the etching plasma may be substantially unchanged or may increase in spite of the height reduction of the focus ring, so that the plasma etching process may be uniformly performed on the whole surface of the substrate.

The inspection data of the pattern structures may be stored as the inspection data in an inspection database in the APC, and may be transferred to the position controller in real-time whenever the inspection process is to be performed. When the inspection data deviates from the reference data, the position controller may drive the focus ring to move upwards to the correct position. Thus, the relative position or the gap distance between the substrate and the focus ring may remain substantially unchanged in spite of the height reduction of the focus ring in the plasma etching process, which may increase the uniformity of the etching plasma over the substrate. Accordingly, the etching defects may be sufficiently prevented, particularly at the edge portion of the substrate, and increase the yield of the semiconductor devices.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A dry etching apparatus, comprising:
a base at a lower portion of a dry etching process chamber;
a substrate holder arranged on the base and configured to hold a substrate;
a focus ring enclosing the substrate holder and configured to uniformly focus an etching plasma to a sheath area over the substrate while a plurality of pattern structures are formed on the substrate;
a driver for driving the focus ring in a vertical direction perpendicular to the base; and
a position controller configured to control a vertical position of the focus ring by selectively driving the driver based on inspection results of the pattern structures.

2. The dry etching apparatus of claim 1, wherein the driver includes:
a support plate for supporting the focus ring;
a connecting rod connected to the support plate and configured to move the support plate upwards and downwards in the vertical direction;
a driving shaft for driving the connecting rod; and
a power source for generating a driving power for driving the connecting rod.

3. The dry etching apparatus of claim 2, wherein the substrate holder includes:
a chuck body arranged on the base and having a lower electrode to which a high frequency electrical power is applied;
an insulating ring for enclosing the chuck body on the base; and
a securing chuck arranged on the chuck body and configured to secure the substrate,
wherein the connecting rod extends into the base through the insulating ring, and
wherein the driving shaft is connected to the power source and the connecting rod in the base.

4. The dry etching apparatus of claim 3, wherein the support plate is ring-shaped and interposed between a bottom surface of the focus ring and upper surfaces of the chuck body and the insulating ring.

5. The dry etching apparatus of claim 3, wherein the connecting rod includes three slender members that are arranged in the vertical direction symmetrically with one another and at an angle of 120° with respect to a central axis of the substrate holder.

6. The dry etching apparatus of claim 3, wherein the driver includes:
a sealing member interposed between the insulating ring and the base; and
a leveler for controlling a level degree of the connecting rod.

7. The dry etching apparatus of claim 2, wherein the position controller includes:
a data port configured to receive inspection data from the inspection results of the pattern structures;
a position signal generator configured to generate a position signal including a correct position of the focus ring when the inspection data is deviated from reference data; and
a driving signal generator for generating a driving signal that drives the focus ring to move to the correct position.

8. The dry etching apparatus of claim 7, wherein the driving signal generator includes:
an encoder configured to detect a current position of the focus ring;
a distance calculator configured to generate a correct distance corresponding to a position difference between the current position and the correct position; and
a signal generator configured to generate a power signal that is applied to the power source and drives the connecting rod to move in the vertical direction by the correct distance.

9. The dry etching apparatus of claim 7, wherein the power source includes a servo motor that is arranged in the base.

10. The dry etching apparatus of claim 7, wherein the substrate holder is smaller than the substrate such that the substrate holder is covered with the substrate and an edge portion of the substrate is spaced apart from the substrate holder,
wherein the focus ring includes a lower top surface that is below a bottom surface of the edge portion of the substrate, an upper top surface that is above a top surface of the substrate, and a slant surface connected to the lower top surface and the upper top surface, and
wherein the position controller includes a stopper configured to stop the focus ring from moving upwards and thereby prevent the contact of the lower top surface of the focus ring and the bottom surface of the substrate.

11. The dry etching apparatus of claim 10, wherein the stopper includes:
a gap detector configured to detect a gap distance in the vertical direction between the lower top surface of the focus ring and the bottom surface of the substrate;
a stopping signal generator configured to generate a stopping signal for stopping the focus ring from moving upwards when the gap distance is smaller than a minimal gap distance; and
a destructive signal generator configured to generate a destructive signal for cancelling the driving signal by a destructive interference in response to the stopping signal.

12. The dry etching apparatus of claim 10, wherein the stopper includes:
a gap calculator configured to calculate a gap distance in the vertical direction by subtracting a moving distance of the focus ring to the correct position from an initial gap distance between the lower top surface of the focus ring and the bottom surface of the substrate at an initial time of the etching process;
a stopping signal generator configured to generate a stopping signal for stopping the focus ring from moving upwards when the calculated gap distance is smaller than a reference distance; and
a destructive signal generator configured to generate a destructive signal for cancelling the driving signal by a destructive interference in response to the stopping signal.

13. The dry etching apparatus of claim 7, further comprising:
an automatic process controller configured to control the dry etching apparatus according to a process algorithm and generate an inspection database from the inspection data that is periodically obtained from the inspection results of the pattern structures and is sorted by inspection items.

14. The dry etching apparatus of claim 13, wherein the data port is communicatively coupled with the inspection database.

15. The dry etching apparatus of claim 13, wherein the inspection items include at least one of a composition of the pattern structure, a line width of the pattern structure, and an etching depth of the dry etching process.

16. A dry etching apparatus comprising:
a dry etching process chamber;
a base arranged at a lower portion of the process chamber;
a substrate holder arranged on the base and configured to hold a substrate;
a focus ring enclosing the substrate holder and configured to form a sheath area over the substrate;
a support plate interposed between a bottom surface of the focus ring and the substrate holder;
a connecting rod connected to the support plate and configured to move the support plate in a direction toward and away from the base; and
a position controller configured to control a vertical position of the focus ring by selectively driving the connecting rod based on inspection results of pattern structures formed on the substrate.

17. The dry etching apparatus of claim 16, further including:
a driving shaft configured to drive the connecting rod; and
a power source configured to generate a driving power to drive the connecting rod.

18. The dry etching apparatus of claim 17, wherein the substrate holder includes:
a chuck body arranged on the base and having a lower electrode to which a high frequency electrical power is applied;
an insulating ring enclosing the chuck body on the base; and
a securing chuck arranged on the chuck body and configured to secure the substrate,
wherein the connecting rod extends into the base through the insulating ring, and
wherein the driving shaft is connected to the power source and the connecting rod in the base.

19. A dry etching apparatus comprising:
a base arranged at a lower portion of a dry etching process chamber;
a substrate holder arranged on the base and configured to hold a substrate;
a focus ring encircling the substrate holder to form a sheath area over the substrate;
a support plate interposed between a bottom surface of the focus ring and the substrate holder;
a connecting rod connected to the support plate for moving the support plate in a vertical direction perpendicular to the base; and
a position controller configured to drive the connecting rod and control a vertical position of the focus ring, the position controller including:
a data port configured to receive inspection data from inspection results of the pattern structures for inspection items, wherein the inspection items include at least one of a composition of the pattern structure, a line width of the pattern structure, and an etching depth,
a position signal generator configured to generate a position signal including a correct position of the focus ring, and
a driving signal generator configured to generate a driving signal to move the focus ring to the correct position.

20. The dry etching apparatus of claim 19, wherein the driving signal generator includes:
an encoder configured to detect a current position of the focus ring;
a distance calculator configured to generate a correct distance corresponding to a difference between the current position and the correct position; and
a signal generator configured to generate a power signal that is applied to a power source and drive the connecting rod to move in the vertical direction by the correct distance.
